(19) United States
(12) Patent Application Publication
(10) Pub. No.: US 2025/0380384 A1
(43) Pub. Date: Dec. 11, 2025

(54) QUICK-LOADING CRYOGENIC COOLING SYSTEMS

(71) Applicant: International Business Machines Corporation, Armonk, NY (US)

(72) Inventors: Ashutosh Rao, White Plains, NY (US); Stephen W. Bedell, Wappingers Falls, NY (US)

(21) Appl. No.: 18/737,033

(22) Filed: Jun. 7, 2024

(51) Int. Cl. H05K 7/20

(52) U.S. Cl. CPC H05K 7/20372; H05K 7/20327

(57) ABSTRACT

A system comprises a cooling chamber, a pre-cooling chamber, and a sample transfer mechanism. The pre-cooling chamber is operatively connected to the cooling chamber. The pre-cooling chamber is configured pre-cool a device to a first cryogenic temperature. The sample transfer mechanism is configured to transfer the device from the pre-cooling chamber into the cooling chamber with the cooling chamber maintained at a second cryogenic temperature, which is the same or less than the first cryogenic temperature.

### BACKGROUND

This disclosure relates generally to quantum computing systems and, in particular, to cryogenic cooling systems for quantum computing systems. A quantum computing system can be implemented using superconducting circuit quantum electrodynamics (cQED) architectures that are constructed using quantum circuit components such as, e.g., superconducting quantum bits and other types of superconducting quantum devices that are controlled using microwave control signals. In general, superconducting quantum bits (qubits) are electronic circuits which are implemented using components such as superconducting tunnel junctions (e.g., Josephson junctions), inductors, and/or capacitors, etc., and which behave as quantum mechanical anharmonic (non-linear) oscillators with quantized states, when cooled to cryogenic temperatures. In addition, a quantum computer comprises various types of cryogenic hardware, such as microwave filters, quantum limited amplifiers, Josephson parametric frequency converters and mixers, isolators, switches, and other microwave components that are implemented in qubit control and readout signal paths etc., for purposes of controlling the operation of superconducting qubits and reading out quantum states of such superconducting qubits.

For purposes of testing and prototyping quantum devices and circuitry in a cryogenic environment, superconducting qubit chips and associated cryogenic hardware can be disposed on a base stage in an innermost chamber (e.g. mixing chamber) of a cryogenic cooling system (e.g., cryostat or dilution refrigerator) for purposes of cooling the superconducting qubit chips and associated cryogenic hardware to a target cryogenic temperature (e.g., millikelvin (mK) temperature) for testing. A bottleneck in throughput testing of superconducting devices in a cryogenic environment is the relatively long time it takes (on the order or days or weeks) for a cryogenic cooling chamber to cool down a superconducting device from room temperature (e.g., 300K) to a target cryogenic temperature (e.g., 20 mK or less) after the superconducting device is loaded into the cryogenic cooling chamber and the cryogenic cooling chamber is activated.

### SUMMARY

Exemplary embodiments of the disclosure include cryogenic cooling systems and methods that are configured to provide expedited cooling of devices (e.g., superconducting devices) for increased throughput of quantum computing component and device testing and prototyping.

For example, an exemplary embodiment includes a system which comprises a cooling chamber, a pre-cooling chamber, and a sample transfer mechanism. The pre-cooling chamber is operatively connected to the cooling chamber, and configured to pre-cool a device to a first cryogenic temperature. The sample transfer mechanism is configured to transfer the device from the pre-cooling chamber into the cooling chamber with the cooling chamber maintained at a second cryogenic temperature, which is the same or less than the first cryogenic temperature.

Another exemplary embodiment includes a system which comprises a cooling chamber, and a pre-cooling chamber. The cooling chamber comprises a plurality of chambers and a movable thermal shielding system. The plurality of chambers comprises an outer chamber and a plurality of inner chambers disposed in a nested configuration, where each inner chamber comprises a respective chamber wall and an aperture formed in the chamber wall. The movable thermal shielding system comprises a plurality of movable thermal shield elements, where each movable thermal shield element is operatively coupled to a given chamber wall of a given inner chamber and configured to close or open the aperture of the given chamber wall. The pre-cooling chamber is operatively connected to a chamber wall of the outer chamber of the cooling chamber. The pre-cooling chamber is configured to pre-cool a device to a first cryogenic temperature before loading the pre-cooled device into the cooling chamber through an output aperture of the pre-cooling chamber. The output aperture of the pre-cooling chamber and the apertures of the chamber walls of the inner chambers of the cooling chamber are laterally aligned to allow the pre-cooled device to be transferred through the apertures from the pre-cooling chamber to an innermost chamber of the plurality of chambers of the cooling chamber.

Another exemplary embodiment includes a method to cool a device. The device is placed into a pre-cooling chamber. The device is pre-cooled in the pre-cooling chamber to a first cryogenic temperature, while the cooling chamber is operating to maintain the cooling chamber at a second cryogenic temperature, which is the same or less than the first cryogenic temperature. The pre-cooled device is transferred from the pre-cooling chamber into the cooling chamber to further cool the pre-cooled device to the second cryogenic temperature.

Other embodiments will be described in the following detailed description of exemplary embodiments, which is to be read in conjunction with the accompanying figures.

### BRIEF DESCRIPTION OF THE DRAWINGS

FIG. 1 schematically illustrates a cryogenic cooling system, according to an exemplary embodiment of the disclosure.

FIGS. 2A and 2B schematically illustrate a thermal shielding system comprising movable thermal shields, which can be implemented within a cryogenic cooling chamber, according to an exemplary embodiment of the disclosure.

FIGS. 3A and 3B schematically illustrate a thermal shielding system comprising movable thermal shields, which can be implemented within a cryogenic cooling chamber, according to another exemplary embodiment of the disclosure.

FIGS. 4A, 4B, and 4C schematically illustrate structural configurations of transfer rods, according to alternate embodiments of the disclosure.

FIGS. 5A, 5B, and 5C schematically illustrate structural configurations of transfer rods, according to other alternate embodiments of the disclosure.

FIG. 6 schematically illustrates structures and techniques for thermally and electrically coupling a sample holder to a base plate in a mixing chamber of a cryogenic cooling chamber, according to exemplary embodiments of the disclosure.

FIG. 7 schematically illustrates a cryogenic cooling system, according to another exemplary embodiment of the disclosure.

FIG. 8 illustrates a flow diagram of a method for utilizing a load-lock chamber and cryogenic cooling chamber for cooling a device, according to an exemplary embodiment of the disclosure.

### DETAILED DESCRIPTION

Exemplary embodiments of the disclosure include cryogenic cooling systems and methods that are configured to provide expedited cooling of devices (e.g., superconducting devices) for increased throughput of quantum computing testing and prototyping.

For example, an exemplary embodiment includes a system which comprises a cooling chamber, a pre-cooling chamber, and a sample transfer mechanism. The pre-cooling chamber is operatively connected to the cooling chamber. The pre-cooling chamber is configured pre-cool a device to a first cryogenic temperature. The sample transfer mechanism is configured to transfer the device from the pre-cooling chamber into the cooling chamber with the cooling chamber maintained at a second cryogenic temperature, which is the same or less than the first cryogenic temperature.

Advantageously, the system facilitates the expedited cool down of a device under test (DUT) for, e.g., testing and prototyping. For example, on a first level, the pre-cooling chamber enables the expedited pre-cooling of a DUT to a first cryogenic temperature, since there is minimal thermal mass within the pre-cooling chamber (e.g., DUT and sample holder on which DUT is mounted) which needs to be cooled, thereby allowing fast pre-cooling. Moreover, on a second level, since the cooling chamber is operated on a continuous basis to maintain the cooling chamber at the target second cryogenic temperature for testing, the amount of time needed to cool down the DUT from the pre-cooled temperature (e.g., 4K) to the target cryogenic temperature (e.g., 4K or less) in the cooling chamber is relatively short. Overall, the use of the pre-cooling chamber to pre-cool DUTs in conjunction with the cooling chamber which is operated on a continuous basis, enables a significant reduction the time (e.g., a timescale on the order of hours) needed to cool a DUT to the target cryogenic temperature for testing, as compared to the time needed (e.g., time scale on order of days or a week) for using the cooling chamber alone to cool down the DUT within the cooling chamber from room temperature (e.g., 300K) to the target cryogenic temperature.

In another exemplary embodiment, which may be combined with one or more of the embodiments of the preceding paragraphs, the system comprises a vacuum pump coupled to the pre-cooling chamber and configured to generate a vacuum pressure level within the pre-cooling chamber which is the same or similar to a vacuum pressure level within the cooling chamber.

In another exemplary embodiment, which may be combined with one or more of the embodiments of the preceding paragraphs, the sample transfer mechanism comprises a sample holder and a transfer rod. The sample holder is configured to fixedly mount the device thereon. The transfer rod is coupled to the sample holder, and configured to transfer the sample holder with the device fixedly mounted thereon from the pre-cooling chamber to the cooling chamber.

In another exemplary embodiment, which may be combined with one or more of the embodiments of the preceding paragraphs, the transfer rod is formed of at least one material which is mechanically rigid and thermally insulating.

In another exemplary embodiment, which may be combined with one or more of the embodiments of the preceding paragraphs, the transfer rod comprises an outer portion and at least one inner portion. The outer portion is formed of a first material. The at least one inner portion is formed of a second material, which is different from the first material.

In another exemplary embodiment, which may be combined with one or more of the embodiments of the preceding paragraphs, the first material comprises stainless steel, and the second material comprises a thermoplastic polymer material.

In another exemplary embodiment, which may be combined with one or more of the embodiments of the preceding paragraphs, the sample holder comprises a screw that is configured to screw the sample holder to a mounting plate within the cooling chamber, and the transfer rod is configured to operatively engage the screw and screw the sample holder to the mounting plate using the transfer rod.

In another exemplary embodiment, which may be combined with one or more of the embodiments of the preceding paragraphs, the sample holder comprises a guide pin that is configured to slidably engage a guide pin slot of the mounting plate.

In another exemplary embodiment, which may be combined with one or more of the embodiments of the preceding paragraphs, the cooling chamber comprises a movable thermal shielding system which is configured to thermally shield the pre-cooling chamber from an inner region of the cooling chamber as the sample transfer mechanism transfers the device from the pre-cooling chamber into the inner region of the cooling chamber.

In another exemplary embodiment, which may be combined with one or more of the embodiments of the preceding paragraphs, the movable thermal shielding system comprises at least one movable thermal shield element which is configured to be disposed in (i) a first position in which the at least one movable thermal shield element covers an aperture of a chamber wall of the inner region of the cooling chamber, and (ii) a second position which opens the aperture to allow the device to pass through the aperture as the device is transferred into or out from the inner region of the cooling chamber.

In another exemplary embodiment, which may be combined with one or more of the embodiments of the preceding paragraphs, the at least one movable thermal shield element comprises one of a passive actuator mechanism and an active actuator mechanism to enable the at least one movable thermal shield element to move between at least the first position and the second position.

In another exemplary embodiment, which may be combined with one or more of the embodiments of the preceding paragraphs, the first cryogenic temperature is in a range of about 1 Kelvin to about 4 Kelvin, and the second cryogenic temperature is about 20 millikelvin or less.

Another exemplary embodiment includes a system which comprises a cooling chamber and a pre-cooling chamber. The cooling chamber comprises a plurality of chambers, and a movable thermal shielding system. The plurality of chambers comprises an outer chamber and a plurality of inner chambers disposed in a nested configuration, wherein each inner chamber comprises a respective chamber wall and an aperture formed in the chamber wall. The movable thermal shielding system comprises a plurality of movable thermal shield elements, wherein each movable thermal shield element is operatively coupled to a given chamber wall of a given inner chamber and configured to close or open the aperture of the given chamber wall. The pre-cooling chamber is operatively connected to a chamber wall of the outer chamber of the cooling chamber, and configured to pre-cool a device to a first cryogenic temperature before loading the pre-cooled device into the cooling chamber through an output aperture of the pre-cooling chamber. The output aperture of the pre-cooling chamber and the apertures of the chamber walls of the inner chambers of the cooling chamber are laterally aligned to allow the pre-cooled device to be transferred through the apertures from the pre-cooling chamber to an innermost chamber of the plurality of chambers of the cooling chamber.

In another exemplary embodiment, which may be combined with one or more of the embodiments of the preceding paragraphs, each movable thermal shield element is configured to be disposed in (i) a first position in which the movable thermal shield element covers the aperture of the given chamber wall, and (ii) a second position which opens the aperture of the given chamber wall to allow the device to pass through the aperture as the device is transferred into or out from the cooling chamber.

In another exemplary embodiment, which may be combined with one or more of the embodiments of the preceding paragraphs, each movable thermal shield element comprises one of a passive actuator mechanism and an active actuator mechanism to enable the movable thermal shield element to move between at least the first position and the second position.

In another exemplary embodiment, which may be combined with one or more of the embodiments of the preceding paragraphs, the system comprises a sample transfer mechanism that is configured to transfer the device from the pre-cooling chamber into the innermost chamber of the plurality of inner chambers of the cooling chamber with the cooling chamber operating to maintain the innermost chamber of the cooling chamber at a second cryogenic temperature, which is the same or less than the first cryogenic temperature.

In another exemplary embodiment, which may be combined with one or more of the embodiments of the preceding paragraphs, the system comprises a vacuum pump coupled to the pre-cooling chamber and configured to generate a vacuum pressure level within the pre-cooling chamber which is the same or similar to a vacuum pressure level within the cooling chamber.

Another exemplary embodiment includes a method to cool a device. The device is placed into a pre-cooling chamber. The device is pre-cooled in the pre-cooling chamber to a first cryogenic temperature, while the cooling chamber is operating to maintain the cooling chamber at a second cryogenic temperature, which is the same or less than the first cryogenic temperature. The pre-cooled device is transferred from the pre-cooling chamber into the cooling chamber to further cool the pre-cooled device to the second cryogenic temperature.

In another exemplary embodiment, which may be combined with one or more of the embodiments of the preceding paragraphs, the method further includes vacuum pumping air from the pre-cooling chamber to generate a vacuum pressure level within the pre-cooling chamber which is the same or similar to a vacuum pressure level within the cooling chamber.

In another exemplary embodiment, which may be combined with one or more of the embodiments of the preceding paragraphs, the first cryogenic temperature is in a range of about 1 Kelvin to about 4 Kelvin, and the second cryogenic temperature is about 20 millikelvin or less.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

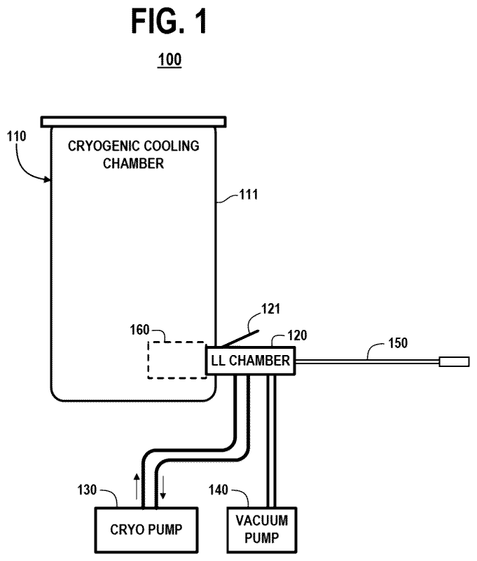

FIG. 1 schematically illustrates a cryogenic cooling system, according to an exemplary embodiment of the disclosure. In particular, FIG. 1 schematically illustrates a cryogenic cooling system 100 which comprises a main cryogenic cooling chamber 110 (alternatively referred to herein as cooling chamber) a vacuum and pre-cooling load-lock chamber 120 (or pre-cooling chamber 120), a cryogenic pump 130, and a vacuum pump 140. In some embodiments, the cryogenic cooling chamber 110 comprises a cryostat. In some embodiments, the cryogenic cooling chamber 110 comprises a dilution refrigerator. The load-lock chamber 120 comprises an auxiliary chamber which is connected to the cryogenic cooling chamber 110 and utilized for loading a pre-cooled device under test (DUT) into the cryogenic cooling chamber 110. In some embodiments, as schematically illustrated in FIG. 1, the load-lock chamber 120 is connected to bottom sidewall of an outer chamber wall 111 of the cryogenic cooling chamber 110 to enable lateral (side) loading of a DUT into the cryogenic cooling chamber 110.

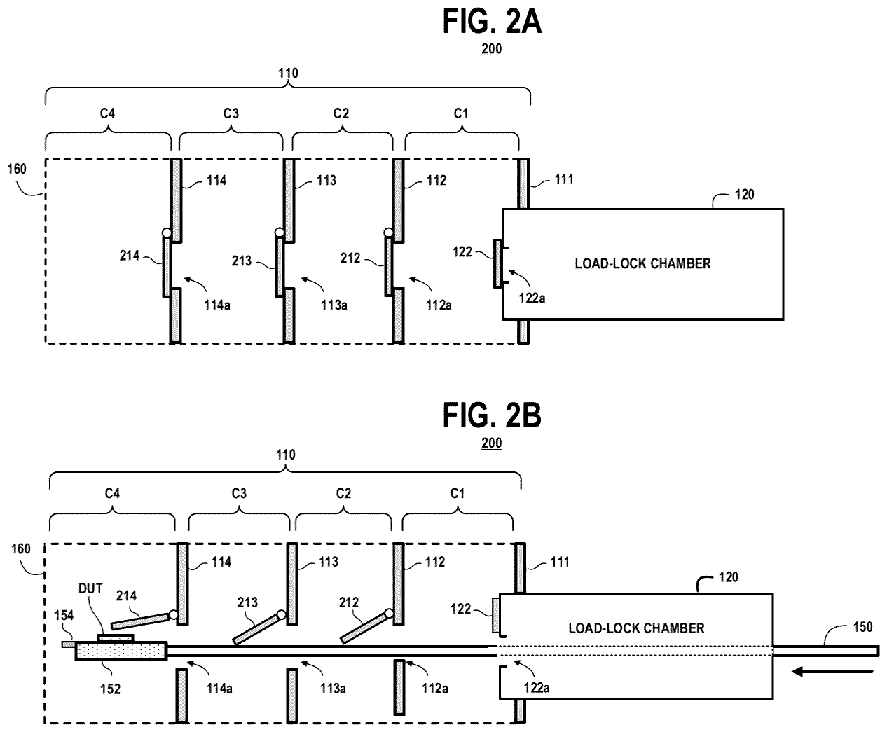

In some embodiments, the load-lock chamber 120 comprises a transfer rod 150, which can be attached and detached to a sample holder 152 (see, e.g., FIGS. 2A and 2B). The transfer rod 150 serves as a mechanical transfer mechanism that allows an individual to move a DUT (which is disposed on the sample holder 152) to and from the main cryogenic cooling chamber 110. In some embodiments, the load-lock chamber 120 comprises a lid 121 on an upper side thereof which can be opened to enable an individual to place a DUT into the load-lock chamber 120, e.g., mount the DUT on the sample holder 152 within the load-lock chamber 120.

The load-lock chamber 120 is an auxiliary chamber that is configured to operate as a vacuum and pre-cooling chamber for pre-cooling a given DUT to a cryogenic temperature (e.g., 4K or less) in a vacuum environment, prior to loading the given DUT into a base stage (e.g., millikelvin stage) of the cryogenic cooling chamber 110. It is to be noted that the terms “pre-cooling chamber,” “load-lock chamber,” and “auxiliary chamber” as used herein are synonymous terms.

As schematically illustrated in FIG. 1, the load-lock chamber 120 is operatively connected to the cryogenic pump 130 and to the vacuum pump 140. The vacuum pump 140 is configured to pump air from the load-lock chamber 120 and generate a vacuum pressure within the load-lock chamber 120. It is to be noted that the term “vacuum pressure” refers to a pressure that is less than, or significantly less than, atmospheric pressure. For example, in some embodiment, the vacuum pump 140 and load-lock chamber 120 are operatively configured to achieve a vacuum pressure in a range of 10⁻⁵ Torr to about 10⁻⁹ Torr. The cryogenic pump 130 is configured to control the flow of a coolant, e.g., liquid helium, into and out of an interior of the load-lock chamber 120 to cool the given DUT to a cryogenic temperature (e.g., 4K temperature or less) while disposed within the load-lock chamber 120. In some embodiments, the load-lock chamber 120 comprises a pulse tube cryocooler configuration in which a sample holder (on which the DUT is mounted) is disposed in contact with a head of the pulse tube cryocooler to cool down the DUT to a cryogenic temperature.

The implementation of the load-lock chamber 120 in conjunction with the cryogenic cooling chamber 110 (e.g., He dilution cryostat) allows the cryogenic cooling chamber 110 to be continuously operated to maintain the base stage (within the cryogenic cooling chamber 110) at a target cryogenic temperature that permits continuous Helium-4 condensation (e.g., less than about 4K), while utilizing the load-lock chamber 120 to (i) pre-cool a DUT in the load-lock chamber 120 down to a cryogenic temperature (e.g., a temperature of 4K or less), and (ii) load the pre-cooled DUT into the continuously operating cryogenic cooling chamber 110. The load-lock chamber 120 allows the Helium-4 to remain in the condensed phase and allows continuous circulation of Helium-3 in the cryogenic cooling chamber 110 during sample exchange, e.g., when a given DUT is loaded into the cryogenic cooling chamber 110, and when the given DUT is removed from the cryogenic cooling chamber 110.

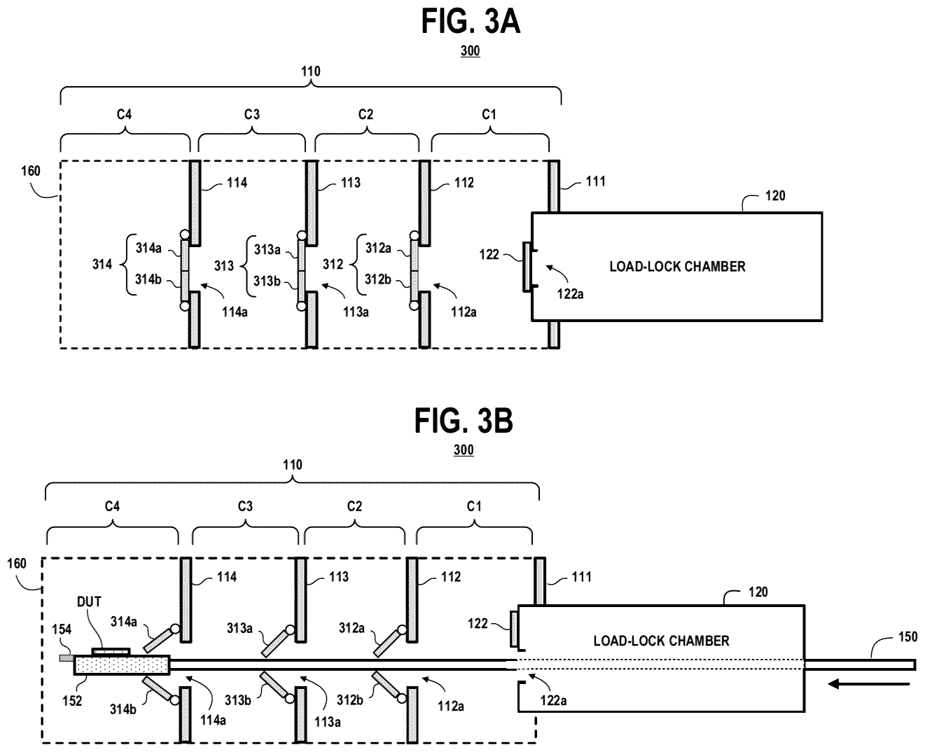

As schematically illustrated in FIG. 1, an inner region 160 of the cryogenic cooling chamber 110 is disposed adjacent to the load-lock chamber 120. The inner region 160 comprises a thermal shielding system comprising movable thermal shields, which is configured to minimize heat transfer into the base stage (or base mixing chamber) of the cryogenic cooling chamber 110 as a pre-cooled DUT is transferred from the load-lock chamber 120 through different inner chambers of the cryogenic cooling chamber 110 and loaded into the base mixing chamber of the cryogenic cooling chamber 110. The thermal shielding system allows the cryogenic cooling chamber 110 to be continuously operated to maintain the base stage (within the cryogenic cooling chamber 110) at a target cryogenic temperature (e.g., about 4K or less) during DUT sample exchange operations. Exemplary embodiments of thermal shielding systems with movable thermal shields will now be discussed in further detail in conjunction with FIGS. 2A, 2B, 3A, and 3B.

For example, FIGS. 2A and 2B schematically illustrate a thermal shielding system comprising movable thermal shields, which can be implemented within a cryogenic cooling chamber, according to an exemplary embodiment of the disclosure. In particular, FIGS. 2A and 2B schematically illustrate a thermal shielding system 200 comprising a plurality of movable thermal shields 212, 213, and 214, which can be implemented within the inner region 160 of the cryogenic cooling chamber 110 of FIG. 1, according to an exemplary embodiment of the disclosure. In some embodiments, as schematically illustrated in FIGS. 2A and 2B, the cryogenic cooling chamber 110 comprises a multi-chamber architecture which comprises a plurality of nested chambers C1, C2, C3, and C4 which enclose each other. For illustrative purposes, FIGS. 2A and 2B show the cryogenic cooling chamber 110 having four nested chambers C1, C2, C3, and C4, although a cryogenic cooling chamber can be designed with other numbers of nested chambers (e.g., 6 nested chambers).

A first chamber C1 is an outermost chamber of the cryogenic cooling chamber 110, and comprises the outer chamber wall 111. A second chamber C2 is disposed within the first chamber C1, and comprises a chamber wall 112. A third chamber C3 is disposed within the second chamber C2, and comprises a chamber wall 113. A fourth chamber C4 comprises an innermost chamber (e.g., base mixing chamber) of the cryogenic cooling chamber 110, and comprises a chamber wall 114. The nested, multi-chamber architecture is designed to enable ultra-low cryogenic temperatures within the cryogenic cooling chamber 110 through progressive cooling. For example, the temperature within the cryogenic cooling chamber 110 is progressively decreased from the first (outermost) chamber C1 to the fourth (innermost) chamber C4, where each chamber serves as a stage for cooling. For example, the first chamber C1 can be a 50K chamber, the second chamber C2 can be a 4K chamber, the third chamber C3 can be a 100 mK chamber, and the fourth chamber C4 (mixing stage chamber) can be a 20 mK (or less) chamber. In some embodiments, the cryogenic cooling chamber 110 implements vacuum isolation spaces between the chambers to prevent heat transfer by convection, wherein a vacuum pressure of about 10⁻⁶ Torr or better provides effective isolation.

As schematically illustrated in FIGS. 2A and 2B, the load-lock chamber 120 is coupled to the outer chamber wall 111 of the first chamber C1, where the load-lock chamber 120 interfaces or mates with the outer chamber wall 111 of the cryogenic cooling chamber 110 using any suitable coupling or mating mechanism which provides vacuum pressure sealing between the load-lock chamber 120 and the cryogenic cooling chamber 110. In some embodiments, the load-lock chamber 120 is coupled to the outer chamber wall 111 such that the sidewall of the load-lock chamber 120 is disposed within the first chamber C1. In some embodiments, the load-lock chamber 120 comprises a slit valve 122 on the sidewall of the load-lock chamber 120. The slit valve 122 can be implemented using any suitable slit valve architecture, which is controlled (opened and closed) using known actuation mechanisms.

As further shown in FIGS. 2A and 2B, the chamber wall 112 of the second chamber C2 comprises an aperture 112a, the chamber wall 113 of the third chamber C3 comprises an aperture 113a, and the chamber wall 114 of the fourth chamber C4 comprises an aperture 114a. The movable thermal shield 212 is coupled to the chamber wall 112 and is configured to cover the aperture 112a. The movable thermal shield 213 is coupled to the chamber wall 113 and is configured to cover the aperture 113a. The movable thermal shield 214 is coupled to the chamber wall 114 and is configured to cover the aperture 114a. In some embodiments, as schematically illustrated in FIGS. 2A and 2B, the movable thermal shields 212, 213, and 214 comprise thermal shield elements that are hingedly connected to the respective chamber walls 112, 113, and 114. In particular, the movable thermal shields 212, 213, and 214 each comprise a single thermal shield element having one end that is connected via a hinge element to the respective chamber walls 112, 113, and 114. It is to be noted that the term “hingedly connected” as used herein broadly refers to any connection or attachment that involves at least one hinge element. The movable thermal shields 212, 213, and 214 are formed of any suitable rigid or semi-rigid material with low thermal conductivity including, but not limited to stainless steel, copper, mylar, etc. In some embodiments, the movable thermal shields 212, 213, and 214 are formed of multiple layers (e.g., 10-20 layers) of aluminized mylar.

FIG. 2A schematically illustrates a state of the movable thermal shields 212, 213, and 214 in which the movable thermal shields 212, 213, and 214 are operatively disposed to cover and close the respective apertures 112a, 113a, and 114a. In this state, the movable thermal shields 212, 213, and 214 cover the respective apertures 112a, 113a, and 114a to provide thermal shielding and isolation between chambers C1, C2, C3, and C4. In addition, FIG. 2A schematically illustrates a state of the load-lock chamber 120 in which the slit valve 122 is closed and covering an output aperture 122a (or output port) of the load-lock chamber 120 to provide thermal and pressure isolation between the load-lock chamber 120 and the cryogenic cooling chamber 110.

Next, FIG. 2B schematically illustrates an operational state of the movable thermal shields 212, 213, and 214 where a DUT disposed on a sample holder 152 is transferred from the load-lock chamber 120 through the chambers C1, C2, and C3 and into the innermost (mixing) chamber C4 using the transfer rod 150 that is coupled to the sample holder 152. In this instance, the DUT is initially mounted to the sample holder 152 in the load-lock chamber 120 with the slit valve 122 closed and covering the output aperture 122a. The DUT is cooled to a target cryogenic temperature (e.g., 4K or less) within the load-lock chamber 120, with a vacuum pressure level in the load-lock chamber 120 that is the same or substantially similar to the vacuum pressure level within the cryogenic cooling chamber 110.

When the DUT temperature and pressure within the load-lock chamber 120 are at target levels, the slit valve 122 is actuated so that the output aperture 122a is opened to allow the sample holder 152 and DUT mounted thereon to be transferred through the output aperture 122a into the cryogenic cooling chamber 110 by an individual pushing the transfer rod 150 in a lateral direction as indicated by the arrow shown in FIG. 2B. As the sample holder 152 with the DUT mounted thereon is laterally transferred towards the innermost (mixing) chamber C4, the movable thermal shields 212, 213, and 214 are opened (either passively or actively) which allows the sample holder 152 with the DUT mounted thereon to pass through the apertures 112a, 113a, and 114a to place the sample holder 152 and DUT into the innermost (mixing) chamber C4.

As schematically illustrated in FIG. 2B, the sample holder 152 comprises an electrical connector 154 which is configured to interface with a corresponding electrical connector of a base plate or base stage in the innermost (mixing) chamber C4. For example, in some embodiments, the electrical connector 154 of the sample holder 152 insertably engages a corresponding electrical connector of a base plate on which the sample holder 152 is disposed (and electrically coupled to), to provide I/O signals between the DUT and a test control system and to provide power to the DUT.

In some embodiments, as schematically illustrated in FIG. 2B, after a given movable thermal shield 212, 213, and 214 has opened and the sample holder 152 and DUT have passed through the respective aperture 112a, 113a, and 114a, the given movable thermal shield 212, 213, and 214 may partially close onto the transfer rod 150 to provide some level of thermal shielding and minimize heat transfer from the load-lock chamber 120 to the cryogenic cooling chamber 110 while permitting lateral motion of the transfer rod 150. It is to be noted that the movable thermal shields 212, 213, and 214 can be implemented using various types of shielding configurations and actuators.

For example, in some embodiments, the movable thermal shields 212, 213, and 214 can be implemented as hinged elements with spring-based actuators. In such embodiments, the movable thermal shields 212, 213, and 214 remain closed by spring force, and are opened when an external force is applied to the movable thermal shields 212, 213, and 214, e.g., when the sample holder 152 pushes against the movable thermal shields 212, 213, and 214 as the sample holder 152 and DUT mounted thereon is transferred through various chambers C1-C4 of the cryogenic cooling chamber 110.

In other embodiments, the movable thermal shields 212, 213, and 214 can be implemented as hinged elements with piezo-based actuators. For example, the movable thermal shields 212, 213, and 214 can be coupled to rotary piezo actuators which control a rotational motion of the movable thermal shields 212, 213, and 214 about a hinge. In such embodiments, the opening and closing of the movable thermal shields 212, 213, and 214 is controlled by applying control signals to the piezo-based actuators. In other embodiments, the movable thermal shields 212, 213, and 214 can be controlled using linear piezo actuators wherein the movable thermal shields 212, 213, and 214 are moved back and forth in a linear direction to open and close the respective apertures 112a, 113a, and 114a.

In other embodiments, the movable thermal shields 212, 213, and 214 can be implemented using deformable material and controlled using soft-matter-based actuators (or soft actuator). In this regard, the movable thermal shields 212, 213, and 214 can be implemented with flexible and compliant material, which comprises sufficient thermal shielding properties, and which can change shape by operation of the soft actuators to open and close the respective apertures 112a, 113a, and 114a.

Moreover, the movable thermal shields 212, 213, and 214 and associated actuators can be configured to provide singly-stable, bi-stable, or multi-stable modes of operations. A singly-stable actuator refers to an actuator that has only one stable equilibrium position. For example, a spring-based hinged mechanism is one of example of a singly-stable actuator, wherein when the spring-based hinged mechanism is in a rest position (with a given movable thermal shield covering and closing a given aperture), it will remain in that rest position until an external force is applied to the given movable thermal shield. A bi-stable actuator refers to an actuator that has two stable equilibrium positions, wherein the actuator can move back and forth between the two stable equilibrium positions. For example, a piezo-based actuator is one of example of a bi-stable actuator, wherein the piezo-based actuator can move a given movable thermal shield 212 from a closed position (first equilibrium position) to an open position (second equilibrium position) by applying a control signal to the piezo-based actuator, and then move the given movable thermal shield from the open position (second equilibrium position) back to the closed position (first equilibrium position) by other control signal to the piezo-based actuator. A multi-stable actuator refers to an actuator that has multiple stable positions. For example, a soft-matter based actuator which comprises compliant or smart materials can have multiple stable dimensions and shapes, etc., in response to control signals.

It is to be noted that in some embodiments, the ends portion of the movable thermal shields 212, 213, and 214 are configured to allow the transfer rod 150 and the sample holder 152 and DUT mounted thereon to be transferred from the innermost (mixing) chamber C1 back into the load-lock chamber 120 without the ends of the movable thermal shields 212, 213, and 214 applying shear stress to the transfer rod 150 and the sample holder 152 and DUT mounted thereon, as an individual pulls the transfer rod 150 to remove the sample holder 152 and DUT from the cryogenic cooling chamber 110. For example, in some embodiments, the movable thermal shields 212, 213, and 214 can be formed of a rigid material (e.g., stainless steel) while the end portions of the movable thermal shields 212, 213, and 214 are formed of a pliable and thermally insulating material such as mylar. This would allow the movable thermal shields 212, 213, and 214 to close down onto the transfer rod 150 to minimize heat transfer from the load-lock chamber 120 to the cryogenic cooling chamber 110, while allowing the transfer rod 150 to be pulled back out from the cryogenic cooling chamber 110 (either alone, or when reconnected with the sample holder 152 and DUT and pulled back to remove the DUT from the cryogenic cooling chamber 110) without the end portions of the movable thermal shields 212, 213, and 214 to impede (e.g. via shear stress) the lateral motion of the transfer rod 150. In other embodiments, the movable thermal shields 212, 213, and 214 are configured to have more than one degree of “closure” permitting different degrees of transfer rod motion. For example, the movable thermal shields 212, 213, and 214 can be motorized or non-motorized bidirectional hinges.

Next, FIGS. 3A and 3B schematically illustrate a thermal shielding system comprising movable thermal shields, which can be implemented within a cryogenic cooling chamber, according to another exemplary embodiment of the disclosure. In particular, FIGS. 3A and 3B schematically illustrate a thermal shielding system 300 comprising a plurality of movable thermal shields 312, 313, and 314, which can be implemented within the inner region 160 of the cryogenic cooling chamber 110 of FIG. 1, according to another exemplary embodiment of the disclosure. Similar to the exemplary embodiment of FIGS. 2A and 2B, the cryogenic cooling chamber 110, as shown in FIGS. 3A and 3B, comprises a multi-chamber architecture having a plurality of nested chambers C1, C2, C3, and C4 which enclose each other. The nested chambers C1, C2, C3, and C4 comprise respective chamber walls 112, 113, and 114 which comprise respective apertures 112a, 113a, and 114a.

In some embodiments, as schematically illustrated in FIGS. 3A and 3B, the movable thermal shields 312, 313, and 314 comprise thermal shield elements that are hingedly connected to the respective chamber walls 112, 113, and 114. In particular, the movable thermal shields 312, 313, and 314 each comprise two thermal shield elements having one end that is connected via a hinge element to the respective chamber walls 112, 113, and 114. In particular, the movable thermal shield 312 comprises a first thermal shield element 312a and a second thermal shield element 312b which are hingedly connected to the chamber wall 112 on opposite sides of the aperture 112a. Similarly, the movable thermal shield 313 comprises a first thermal shield element 313a and a second thermal shield element 313b which are hingedly connected to the chamber wall 113 on opposite sides of the aperture 113a, and the movable thermal shield 314 comprises a first thermal shield element 314a and a second thermal shield element 314b which are hingedly connected to the chamber wall 114 on opposite sides of the aperture 114a.

FIG. 3A schematically illustrates a state of the movable thermal shields 312, 313, and 314 in which the movable thermal shields 312, 313, and 314 are operatively disposed to cover and close the respective apertures 112a, 113a, and 114a. In this state, the movable thermal shields 312, 313, and 314 cover the respective apertures 112a, 113a, and 114a to provide thermal shielding and isolation between chambers C1, C2, C3, and C4. In addition, 3A schematically illustrates a state of the load-lock chamber 120 in which the slit valve 122 is closed and covering an output aperture 122a (or output port) of the load-lock chamber 120 to provide thermal and pressure isolation between the load-lock chamber 120 and the cryogenic cooling chamber 110.

Next, FIG. 3B schematically illustrates an operational state of the movable thermal shields 312, 313, and 314 where a DUT disposed on a sample holder 152 is transferred from the load-lock chamber 120 through the opened slit valve 122, and through the chambers C1, C2, and C3 and into the innermost (mixing) chamber C4 using the transfer rod 150 which is coupled to the sample holder 152, and which is pushed by an individual in a lateral direction as indicated by the arrow shown in FIG. 3B. As the sample holder 152 with the DUT mounted thereon is laterally transferred towards the innermost (mixing) chamber C4, the movable thermal shields 312, 313, and 314 are opened (either passively or actively) which allows the sample holder 152 with the DUT mounted thereon to pass through the apertures 112a, 113a, and 114a to place the sample holder 152 and DUT into the innermost (mixing) chamber C4.

In some embodiments, as schematically illustrated in FIG. 3B, after a given movable thermal shields 312, 313, and 314 has opened and the sample holder 152 and DUT have passed through the respective aperture 112a, 113a, and 114a, the respective pairs of first and second thermal shield elements 312a/312b, 313a/313b, and 314a/314b may partially close onto the transfer rod 150 to provide some level of thermal shielding and minimize heat transfer from the load-lock chamber 120 to the cryogenic cooling chamber 110 while permitting lateral motion of the transfer rod 150. As compared to the movable thermal shields 212, 213, and 214 shown in FIG. 2B, the movable thermal shields 312, 313, and 314 in the partial open state as shown in FIG. 3B, provide a higher level of thermal shielding to minimize heat transfer from the load-lock chamber 120 to the cryogenic cooling chamber 110 as the DUT is transferred into the innermost (mixing) chamber C4.

The movable thermal shields 312, 313, and 314 can be implemented using various types of shielding configurations and actuators as discussed above. For example, the movable thermal shields 312, 313, and 314 can be formed of any suitable rigid or semi-rigid material with low thermal conductivity including, but not limited to stainless steel, mylar, etc. The movable thermal shields 312, 313, and 314 can be controlled using passive or active actuator mechanisms (e.g., spring-based, piezo-based, or soft-matter based actuators, etc.). The movable thermal shields 312, 313, and 314 and associated actuators may be configured to provide singly-stable, bi-stable, or multi-stable operating modes.

It is to be noted that in some embodiments, a transfer rod (e.g., transfer rod 150) comprises an engineered structure which is (i) mechanically rigid to provide structural stability for transferring a sample holder with a DUT mounted thereon into and out of the cryogenic cooling chamber 110, and which is (ii) thermally insulating to minimize heat flow from the load-lock chamber 120 to the cryogenic cooling chamber 110 and thereby minimize the thermal load of the transfer rod 150 on the cryogenic cooling chamber 110. In this regard, a transfer rod can be fabricated from single material, multiple materials, compositive materials, etc., which are suitable to provide transfer rod structure that is mechanically rigid and thermally insulating.

For example, in some embodiments, the transfer rod 150 can be fabricated using a single material, such as stainless steel, which has sufficient rigidity, and which has sufficiently low thermal conductivity. However, a transfer rod made of stainless steel alone may not provide sufficient thermal isolation in instances where the temperature differential between the load-lock chamber 120 and the innermost (mixing) chamber of the cryogenic cooling chamber 110 is relatively large (e.g., differential between 4K and 20 mK). In this regard, the transfer rod 150 can be fabricated with different materials which, in combination, provide the desired mechanical rigidity and thermally insulating properties for a given application.

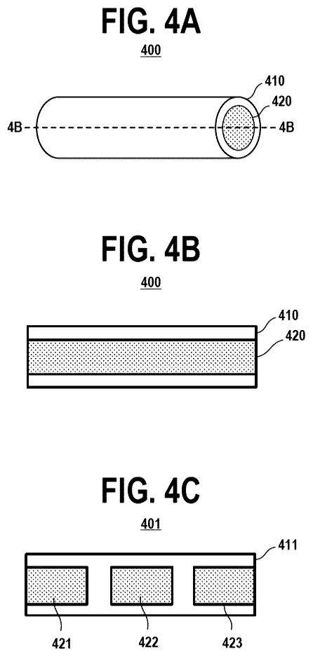

For example, FIGS. 4A, 4B, and 4C schematically illustrate structural configurations of transfer rods, according to alternate embodiments of the disclosure. In particular, FIG. 4A schematically illustrates a portion of a transfer rod 400 which comprises an outer portion 410 (e.g., outer shield portion) and an inner portion 420 (e.g., inner bulk portion) which are fabricated with different materials. For example, the outer portion 410 can be made of stainless steel, or some other suitable material which has high mechanical rigidity and/or low thermal conductivity. The inner portion 420 can be made of a thermoplastic polymer such as polytetrafluoroethylene (PTFE) (e.g., Teflon brand) which has a thermal conductivity that is lower than the thermal conductivity of the material of the outer portion 410. The inner portion 420 can be made of some other suitable material that has high mechanical rigidity and/or low thermal conductivity.

FIG. 4B is a schematic cross-sectional view of the transfer rod 400 along line 4B-4B of FIG. 4A. FIG. 4B illustrates an exemplary embodiment in which the inner portion 420 is continuous along the entire length of the transfer rod 400. On the other hand, FIG. 4C is a schematic cross-sectional view of a transfer rod 401 according to another exemplary embodiment of the disclosure, wherein the transfer rod 401 comprises an outer portion 411, and segmented inner portion which comprise a plurality of inner segments 421, 422, and 423 that are intermittently formed along an entire length of the transfer rod 401.

In some embodiments, the outer portion 411 is formed of stainless steel, or some other suitable material which has high mechanical rigidity and/or low thermal conductivity. The plurality of inner segments 421, 422, and 423 can be formed of a thermoplastic polymer such as polytetrafluoroethylene (PTFE) (e.g., Teflon brand) which has a thermal conductivity that is lower than the thermal conductivity of the material of the outer portion 410. The exemplary embodiments of FIGS. 4A, 4B, and 4C illustrate transfer rods with outer surface portions and inner bulk portions that are engineered to have low thermal conductivity and accommodate physical strain and deformation from operation.

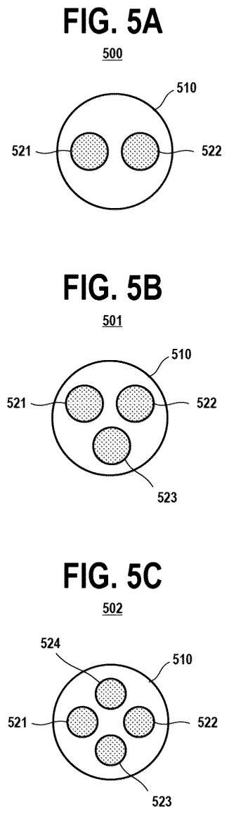

Next, FIGS. 5A, 5B, and 5C schematically illustrate structural configurations of transfer rods, according to other alternate embodiments of the disclosure. For example, FIG. 5A schematically illustrates a cross-section of a transfer rod 500 which comprises an outer portion 510 (e.g., outer shield portion) and multiple inner portions including a first inner portion 521 and a second inner portion 522 (e.g., first and second inner bulk portions), which are fabricated with different materials. For example, the outer portion 510 can be made of stainless steel, or some other suitable material which has high mechanical rigidity and/or low thermal conductivity. The first and second inner portions 521 and 522 can be made of the same material or different materials. For example, in some embodiment, the first and second inner portions 521 and 522 are each formed of a thermoplastic polymer such as polytetrafluoroethylene (PTFE) (e.g., Teflon brand) which has a thermal conductivity that is lower than the thermal conductivity of the material of the outer portion 510.

Next, FIG. 5B schematically illustrates a cross-section of a transfer rod 501 which comprises an outer portion 510 (e.g., outer shield portion) and multiple inner portions including a first inner portion 521, a second inner portion 522, and a third inner portion 523 (e.g., first, second, and third inner bulk portions). Similarly, FIG. 5C schematically illustrates a cross-section of a transfer rod 502 which comprises an outer portion 510 (e.g., outer shield portion) and multiple inner portions including a first inner portion 521, a second inner portion 522, a third inner portion 523, and a fourth inner portion 524 (e.g., first, second, third, and fourth inner bulk portions). Similar to the exemplary embodiments discussed above, the outer portions 510 of the exemplary transfer rods 501 and 502 can be fabricated with, e.g., stainless steel, and the inner portions 521, 522, 523, and 524 of the exemplary transfer rods 501 and 502 can be fabricated using the same material, e.g., same thermoplastic polymer. In other embodiments, one or more of the inner portions 521, 522, 523, and 524 can be fabricated using different materials.

Moreover, in some embodiments, the inner portions 521, 522, 523, and 524 of the exemplary transfer rods 501 and 502 can be continuous structures formed along an entire length of the transfer rods 501 and 502, such as shown in FIG. 4B. In other embodiments, at least one of the inner portions 521, 522, 523, and 524 of the exemplary transfer rods 501 and 502 comprise segmented portions that that are intermittently formed along an entire length of the transfer rods 501 and 502, such as shown in FIG. 4C.

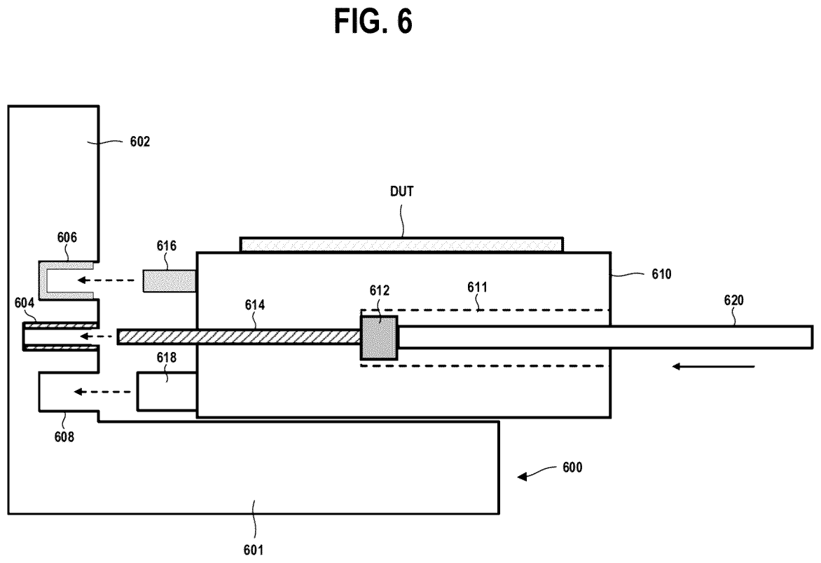

Next, FIG. 6 schematically illustrates structures and techniques for thermally and electrically coupling a sample holder to a base plate in a mixing chamber of a cryogenic cooling chamber, according to exemplary embodiments of the disclosure. In particular, FIG. 6 schematically illustrates an exemplary base plate 600 (or mounting plate 600) of a mixing chamber within a cryogenic cooling chamber. The base plate 600 comprises a first portion 601 (or horizontal plate), a second portion 602 (or vertical plate), a threaded hole 604, an electrical connector 606, and a guide pin slot 608, which are disposed in the second portion 602. In addition, FIG. 6 schematically illustrates an exemplary sample holder 610 on which a DUT is mounted. The sample holder 610 comprises an interior channel 611, a screw head 612 and threaded screw 614, an electrical connector 616, and a guide pin 618. In some embodiments, the base plate 600 is formed copper with gold-plated surfaces (gold-plated copper). Moreover, in some embodiments, the sample holder 610 is formed of gold-plate copper.

As schematically illustrated in FIG. 6, the interior channel 611 of the sample holder 610 is configured to insertably receive a transfer rod 620 which, as noted above, is utilized to transfer the sample holder 610 (and DUT mounted thereon) from a load-lock chamber through the nested chambers of the cryogenic cooling chamber, into the mixing chamber wherein the sample holder 610 is thermally and electrically coupled to the base plate 600. In some embodiments, as shown in FIG. 6, the end of the transfer rod 620 is configured to operatively engage the screw head 612 at the end region of the interior channel 611, wherein the transfer rod 620 is (i) manipulated to push the sample holder 610 towards the second portion 602 (vertical plate) of the base plate 600 with the end of the threaded screw 614 aligned with the threaded hole 604, and then (ii) rotated to turn the threaded screw 614 within the threaded hole 604 to thereby screw the sample holder 610 to the base plate 600. In some embodiments, the end of the transfer rod 620 comprises a screw bit (e.g., a hex key-shaped bit) which operatively engages the screw head 612, wherein the transfer rod 620 is rotated to screw the sample holder 610 to the base plate 600. In other embodiments, the transfer rod 620 is designed to have a second concentric or non-concentric internal mounting rod that is housed within the transfer rod 620, wherein the internal mounting rod is configured to operatively engage the screw head 612 and be rotated to screw the sample holder 610 to the base plate.

As the sample holder 610 is being screwed to the base plate 600, the electrical connector 616 of the sample holder 610 insertably engages the electrical connector 606 of the base plate 600, and the guide pin 618 of the sample holder 610 insertably engages the guide pin slot 608 of the base plate 600. The screw mechanism is configured to ensure that the sample holder 610 makes good thermal and electrical connections to the base plate 600. In some embodiments, the electrical connectors 606 and 616 comprise gold-plated copper electrical connections to ensure good electrical and thermal contact, and to prevent oxidation of the metal surfaces. The guide pin 618 is configured to achieve enhanced mechanical stability and thermal conductivity between the sample holder 610 and the base plate 600, when the guide pin 618 is inserted into the guide pin slot 608 of the base plate 600.

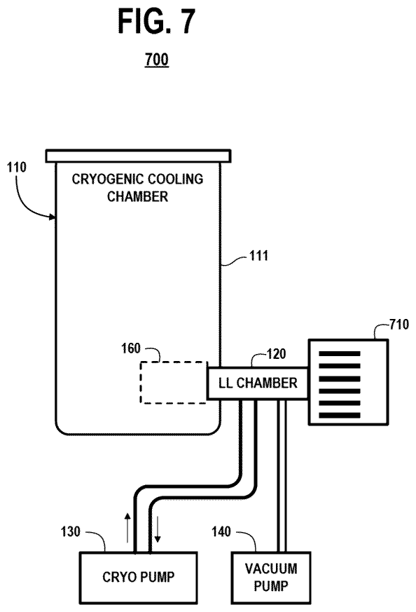

FIG. 7 schematically illustrates a cryogenic cooling system, according to an exemplary embodiment of the disclosure. In particular, FIG. 7 schematically illustrates a cryogenic cooling system 700 which is similar to the cryogenic cooling system 100 of FIG. 1, except that the cryogenic cooling system 700 comprises a robotic system 710 that is configured to automatically load a DUT into the load-lock chamber 120 and transfer the DUT from the load-lock chamber 120 into the continuously and actively operating cryogenic cooling chamber 110. In addition, the robotic system 710 is configured to automatically transfer the DUT from the continuously and actively operating cryogenic cooling chamber 110 into the load-lock chamber 120, and then automatically reload another DUT into the load-lock chamber 120 and transfer the DUT from the load-lock chamber 120 into the continuously and actively operating cryogenic cooling chamber 110.

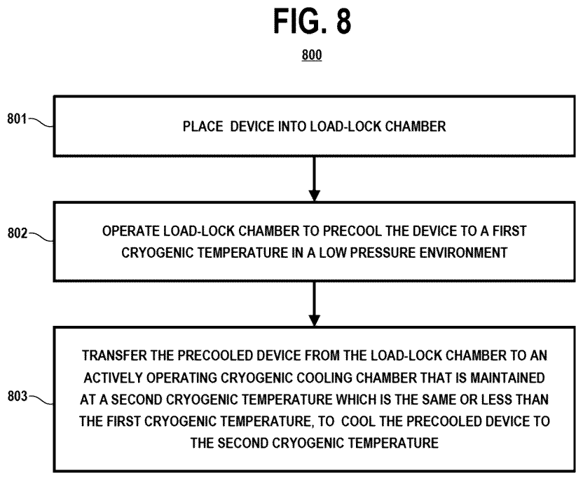

FIG. 8 illustrates a flow diagram of a method for utilizing a load-lock chamber and cryogenic cooling chamber for cooling a device, according to an exemplary embodiment of the disclosure. In particular, FIG. 8 illustrates a method 800 for utilizing a load-lock chamber, which is operatively connected to cryogenic cooling chamber, to pre-cool a given DUT to a target cryogenic temperature, and the transfer the pre-cooled DUT into the continuously and actively operating cryogenic cooling chamber (e.g., cryostat or dilution refrigerator). For illustrative purposes, the method 800 will be discussed in conjunction with the cryogenic cooling systems 100 and 700 of FIGS. 1 and 7, and sample transfer and loading mechanisms as discussed above.

As an initial step, a DUT is placed into the load-lock chamber 120 (block 801). In some embodiments, the DUT is manually loaded into the load-lock chamber 120 by opening the lid 121 thereof (FIG. 1) and placing the DUT on a sample holder in the load-lock chamber 120. In other embodiments, the DUT is automatically loaded into the load-lock chamber 120 via operation of the robotic system 710 (FIG. 7). As noted above, the load-lock chamber 120 is operatively connected to a cryogenic cooling chamber 110 which is continuously and actively operated to maintain an inner mixing chamber at a target cryogenic temperature.

Next, the load-lock chamber 120 is operated to cool the DUT to a first cryogenic temperature in a low-pressure environment within the load-lock chamber 120 (block 802). For example, as noted above, in some embodiments, the load-lock chamber 120 is configured to pre-cool the DUT to a first cryogenic temperature which is in a range of about 1K to 4K. Moreover, the load-lock chamber 120 is coupled to vacuum pump 140 which is configured to pull air from the load-lock chamber 120 and provide a vacuum pressure level within the load-lock chamber 120, which is the same or similar to the vacuum pressure level within the continuously and actively operating cryogenic cooling chamber 110.

Next, the DUT (mounted on the sample holder) is transferred from the load-lock chamber 120 to the actively operating cryogenic cooling chamber 110 which is maintained at a second cryogenic temperature which is the same or less than the first cryogenic temperature (block 803). For example, as noted above, in some embodiments, the cryogenic cooling chamber 110 is actively operated on a continuous basis to maintain the innermost (mixing) chamber at a target cryogenic temperature (e.g., 20 mK or less). In this regard, with the DUT pre-cooled to the first cryogenic temperature (e.g., range of 1K to 4K), the time for cooling down the DUT to the target (second) cryogenic temperature is reduced. As noted above, the sample holder with the DUT mounted thereon can be manually transferred (via a manual transfer rod) or automatically transferred (via the robotic system) from the load-lock chamber 120 into the actively operating cryogenic cooling chamber 110. When transferring the DUT in and out of the actively operating cryogenic cooling chamber 110, the thermal shielding system, which comprises the movable thermal shields, serves to minimizes the amount heat transfer to the innermost (mixing) chamber of the cryogenic cooling chamber 110 so that the cryogenic cooling chamber 110 can be continuously and actively operated to maintain the innermost (mixing) chamber at the target cryogenic temperature for testing and prototyping DUTs.

It is to be appreciated that the exemplary cryogenic cooling systems and techniques as described herein facilitate the expedited cool down of DUTs for testing and prototyping the DUTs. For example, on a first level, the load-lock chamber 120 enables the expedited pre-cooling of a DUT to a target cryogenic temperature (e.g., 1K to 4K). Indeed, when operating the load-lock chamber, there is minimal thermal mass within the load-lock chamber, which allows fast pre-cooling. Indeed, essentially, the only mass within the load-lock chamber 120 which needs to be pre-cooled is the sample holder and the DUT mounted thereon. Moreover, on a second level, since the main cryogenic cooling chamber is actively operated on a continuous basis to maintain the innermost (mixing) chamber at the target cryogenic temperature (e.g., 20 mK) for testing, the amount of time needed to cool down the sample holder and DUT mounted thereon from the pre-cooled temperature (e.g., 4K) to the target cryogenic temperature (e.g., 20 mK) in the innermost (mixing) chamber is relatively short.

Overall, the use of the load-lock chamber to pre-cool DUTs in conjunction with a cryogenic cooling chamber that is actively operated on a continuous basis, enables a significant reduction the time (e.g., a timescale on the order of hours) needed to cool a DUT to a target cryogenic temperature for testing, as compared to the time needed (e.g., time scale on order of days or a week) for using the cryogenic cooling chamber alone to cool down DUT from room temperature (e.g., 300K) to a target cryogenic temperature (e.g., 4K or less) by placing the warm DUT into a non-operating cryogenic cooling chamber, and then activating the cryogenic cooling chamber to cool down the DUT from room temperature (300K) to a target cryogenic temperature (e.g., 20 mK) for proper testing and prototyping. In addition, the use of the load-lock chamber 120 not only enables reduction in the cool-down time to the millikelvin regime, but also enables a reduction in the number of pumping/condensation cycles when pre-cooling a DUT to a below ˜4K.

Advantageously, the exemplary cryogenic cooling systems and methods enable expedited cooling of devices (e.g., devices with superconducting qubits, devices with spin qubits, etc.) for increased throughput of quantum computing testing and prototyping which, turned, facilities an increased rate of development of new materials and devices for use in quantum computing by virtue of the quick-turnaround device testing in a millikelvin environment. Indeed, as noted above, the exemplary cryogenic cooling systems and methods described herein enable millikelvin device testing on a timescale of hours rather than days or weeks, which increases the rate of device and material learning. The quick turnaround testing enabled by the expedited cooling rates provided by the exemplary cryogenic cooling systems and methods described herein exemplary are particularly advantageous for increasing the pace of quantum computing research.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and to enable others of ordinary skill in the art to understand the embodiments disclosed herein.

What is claimed is:

1. A system, comprising:
a cooling chamber;
a pre-cooling chamber operatively connected to the cooling chamber, wherein the pre-cooling chamber is configured to pre-cool a device to a first cryogenic temperature; and
a sample transfer mechanism configured to transfer the device from the pre-cooling chamber into the cooling chamber with the cooling chamber maintained at a second cryogenic temperature, which is the same or less than the first cryogenic temperature.

2. The system of claim 1, further comprising a vacuum pump coupled to the pre-cooling chamber and configured to generate a vacuum pressure level within the pre-cooling chamber which is the same or similar to a vacuum pressure level within the cooling chamber.

3. The system of claim 1, wherein the sample transfer mechanism comprises:
a sample holder configured to fixedly mount the device thereon; and
a transfer rod coupled to the sample holder, wherein the transfer rod is configured to transfer the sample holder with the device fixedly mounted thereon from the pre-cooling chamber into the cooling chamber.

4. The system of claim 3, wherein the transfer rod is formed of at least one material which is mechanically rigid and thermally insulating.

5. The system of claim 3, wherein:
the transfer rod comprises an outer portion and at least one inner portion;
the outer portion is formed of a first material; and
the at least one inner portion is formed of a second material, which is different from the first material.

6. The system of claim 5, wherein:
the first material comprises stainless steel; and
the second material comprises a thermoplastic polymer material.

7. The system of claim 3, wherein:
the sample holder comprises a screw that is configured to screw the sample holder to a mounting plate within the cooling chamber; and
the transfer rod is configured to operatively engage the screw and screw the sample holder to the mounting plate using the transfer rod.

8. The system of claim 7, wherein the sample holder comprises a guide pin that is configured to slidably engage a guide pin slot of the mounting plate.

9. The system of claim 1, wherein the cooling chamber comprises a movable thermal shielding system which is configured to thermally shield the pre-cooling chamber from an inner region of the cooling chamber as the sample transfer mechanism transfers the device from the pre-cooling chamber into the inner region of the cooling chamber.

10. The system of claim 9, wherein the movable thermal shielding system comprises at least one movable thermal shield element which is configured to be disposed in (i) a first position in which the at least one movable thermal shield element covers an aperture of a chamber wall of the inner region of the cooling chamber, and (ii) a second position which opens the aperture to allow the device to pass through the aperture as the device is transferred into or out from the inner region of the cooling chamber.

11. The system of claim 10, wherein the at least one movable thermal shield element comprises one of a passive actuator mechanism and an active actuator mechanism to enable the at least one movable thermal shield element to move between at least the first position and the second position.

12. The system of claim 1, wherein:
the first cryogenic temperature is in a range of about 1 Kelvin to about 4 Kelvin; and
the second cryogenic temperature is about 20 millikelvin or less.

13. A system, comprising:
a cooling chamber comprising:
a plurality of chambers comprising an outer chamber and a plurality of inner chambers disposed in a nested configuration, wherein each inner chamber comprises a respective chamber wall and an aperture formed in the chamber wall; and
a movable thermal shielding system comprising a plurality of movable thermal shield elements, wherein each movable thermal shield element is operatively coupled to a given chamber wall of a given inner chamber and configured to close or open the aperture of the given chamber wall; and
a pre-cooling chamber operatively connected to a chamber wall of the outer chamber of the cooling chamber, and configured to pre-cool a device to a first cryogenic temperature before loading the pre-cooled device into the cooling chamber through an output aperture of the pre-cooling chamber;
wherein the output aperture of the pre-cooling chamber and the apertures of the chamber walls of the inner chambers of the cooling chamber are laterally aligned to allow the pre-cooled device to be transferred through the apertures from the pre-cooling chamber to an innermost chamber of the plurality of chambers of the cooling chamber.

14. The system of claim 13, wherein each movable thermal shield element is configured to be disposed in (i) a first position in which the movable thermal shield element covers the aperture of the given chamber wall, and (ii) a second position which opens the aperture of the given chamber wall to allow the device to pass through the aperture as the device is transferred into or out from the cooling chamber.

15. The system of claim 14, wherein each movable thermal shield element comprises one of a passive actuator mechanism and an active actuator mechanism to enable the movable thermal shield element to move between at least the first position and the second position.

16. The system of claim 13, further comprising a sample transfer mechanism that is configured to transfer the device from the pre-cooling chamber into the innermost chamber of the plurality of inner chambers of the cooling chamber with the cooling chamber operating to maintain the innermost chamber of the cooling chamber at a second cryogenic temperature, which is the same or less than the first cryogenic temperature.

17. The system of claim 13, further comprising a vacuum pump coupled to the pre-cooling chamber and configured to generate a vacuum pressure level within the pre-cooling chamber which is the same or similar to a vacuum pressure level within the cooling chamber.

18. A method, comprising:
placing a device into a pre-cooling chamber which is coupled to a cooling chamber;
pre-cooling the device in the pre-cooling chamber to a first cryogenic temperature, while the cooling chamber is operating to maintain the cooling chamber at a second cryogenic temperature, which is the same or less than the first cryogenic temperature; and
transferring the pre-cooled device from the pre-cooling chamber into the cooling chamber to further cool the pre-cooled device to the second cryogenic temperature.

19. The method of claim 18, further comprising vacuum pumping air from the pre-cooling chamber to generate a vacuum pressure level within the pre-cooling chamber which is the same or similar to a vacuum pressure level within the cooling chamber.

20. The method of claim 18, wherein:
the first cryogenic temperature is in a range of about 1 Kelvin to about 4 Kelvin; and
the second cryogenic temperature is about 20 millikelvin or less.
